(19) United States
(12) Patent Application Publication
(10) Pub. No.: US 2025/0311452 A1
(43) Pub. Date: Oct. 2, 2025

(54) ELECTRONIC PACKAGE AND MANUFACTURING METHOD THEREOF

(71) Applicant: SILICONWARE PRECISION INDUSTRIES CO., LTD., Taichung City (TW)

(72) Inventors: Che-Yu LEE, Taichung City (TW); Chi-Ching HO, Taichung City (TW); Chao-Chiang PU, Taichung City (TW); Yi-Min FU, Taichung City (TW); Jui-Cheng LIN, Taichung City (TW)

(73) Assignee: SILICONWARE PRECISION INDUSTRIES CO., LTD., Taichung City (TW)

(21) Appl. No.: 18/769,937

(22) Filed: Jul. 11, 2024

(30) Foreign Application Priority Data
Apr. 2, 2024 (TW) 113112561

(51) Int. Cl. H01L 27/144; G02B 6/42; H01L 23/00; H01L 23/31; H01L 23/49; H01L 23/538; H01L 25/10

(52) U.S. Cl. CPC H10F 39/10; G02B 6/4206; H01L 24/24; H01L 25/105; H01L 23/3107; H01L 23/49; H01L 23/5383; H01L 24/16; H01L 24/32; H01L 24/73; H01L 2224/16227; H01L 2224/24145; H01L 2224/32225; H01L 2224/73204

(57) ABSTRACT

The present disclosure provides an electronic package having an electronic module, an optoelectronic component disposed on and electrically connected to the electronic module, and a lens module disposed on a side of the optoelectronic component. By the implementation of the present disclosure, the electronic package can be used with a laser without the need to provide a shelf for supporting and fixing an optical fiber. Therefore, the structure and manufacturing process of the electronic package can be effectively simplified, thereby improving the yield and the speed of manufacturing and reducing the manufacturing costs.

### BACKGROUND

### 1. Technical Field

The present disclosure relates to a semiconductor packaging technology, and more particularly, to an electronic package with an optoelectronic component and the manufacturing method thereof.

### 2. Description of Related Art

With the vigorous development of the electronics industry and communication technology, the application of the fifth-generation (5G) communication technology has expanded nowadays to the fields such as Internet of Things (IoT), Industrial Internet of Things (IIoT), Cloud, artificial intelligence (AI), autonomous cars, medical, etc., and all aspects of these fields. With the expansion of application fields and aspects, an extremely large amount of data has been generated that needs to be efficiently transmitted, processed, and stored. Therefore, the industry has begun to enter the era of optical communication, using “light” instead of “electricity” as the carrier of data transmission.

With the development of optical communication technology, silicon photonics components and related technologies have begun to receive attention. However, as shown in FIG. 1, a semiconductor package 1 utilizing the existing silicon photonics technology must be used in cooperation with an optical fiber OF. This conventional semiconductor package 1 using silicon photonics technology includes an electronic integrated circuit (EIC) component 11 and a photonic integrated circuit (PIC) component 12. In order to connect and fix the optical fiber OF, a shelf 13 for carrying the optical fiber OF must be disposed on the PIC component 12 or on a location near the PIC component 12. Therefore, the requirements for the overall structural strength and manufacturing process of the PIC component 12 and the semiconductor package 1 are relatively high, making the manufacturing process too complicated, which not only slows down the process speed, but also makes it difficult to maintain or improve the yield, resulting in the inability to reduce manufacturing costs.

Therefore, how to overcome the above-mentioned problems of conventional techniques has become an urgent issue to be solved.

### SUMMARY

In view of the aforementioned shortcomings of the prior art, the present disclosure provides an electronic package, comprising: an electronic module; an optoelectronic component disposed on and electrically connected to the electronic module; and a lens module disposed on a side of the optoelectronic component.

The present disclosure further provides a manufacturing method of an electronic package, comprising: providing an electronic module; disposing an optoelectronic component on the electronic module and electrically connecting the optoelectronic component to the electronic module; and disposing a lens module on a side of the optoelectronic component.

In the aforementioned electronic package and the manufacturing method thereof, the electronic module includes an electronic component that is electrically connected to the optoelectronic component.

In the aforementioned electronic package and the manufacturing method thereof, the electronic component is an electronic IC (EIC).

In the aforementioned electronic package and the manufacturing method thereof, the optoelectronic component is a photonic IC (PIC).

In the aforementioned electronic package and the manufacturing method thereof, the optoelectronic component has a recess, such that a portion of the lens module is accommodated within the recess and another portion of the lens module bulges out from the recess.

In the aforementioned electronic package and the manufacturing method thereof, the recess is formed on a top side or a bottom side of the optoelectronic component.

As can be seen from the above, the electronic package and the manufacturing method thereof of the present disclosure mainly provide a lens module for receiving optical signals in the form of lasers in the electronic package so that the electronic package can be used in cooperation with the laser without the need to set a shelf for carrying and fixing the optical fiber. Therefore, the structure and manufacturing method thereof can be effectively simplified, thereby improving the yield and the speed of manufacture and reducing the manufacturing cost.

### BRIEF DESCRIPTION OF THE DRAWINGS

FIG. 1 is a schematic view of a structure for a conventional semiconductor package adopting the silicon photonic technology.

FIG. 2A to FIG. 2D-1 and FIG. 2E-1 are schematic views of an embodiment of an electronic package and a manufacturing method thereof according to the present disclosure.

FIG. 2D-2, FIG. 2E-2 are schematic views of a variant aspect of embodiment according to the present disclosure.

FIG. 2D-3, FIG. 2E-3 are schematic views of another variant aspect of an embodiment according to the present disclosure.

### DETAILED DESCRIPTION

Embodiments of the present disclosure are illustrated using the following examples. One of ordinary skill in the art can readily appreciate other advantages and technical effects of the present disclosure upon reading the content of this specification.

It should be noted that the structures, ratios, sizes, etc. shown in the drawings appended to this specification are to be construed in conjunction with the disclosure of this specification in order to facilitate understanding of those skilled in the art. They are not meant to limit the implementations of the present disclosure, and therefore have no substantial technical meaning. Any modifications of the structures, changes of the ratio relationships or adjustments of the sizes, are to be construed as falling within the range covered by the technical content disclosed herein to the extent of not causing changes in the technical effects created and the objectives achieved by the present disclosure. Meanwhile, terms such as “on,” “first,” “second,” “a,” and the like recited herein are for illustrative purposes, and are not meant to limit the scope in which the present disclosure can be implemented. Any variations or modifications to their relative relationships, without changes in the substantial technical content, should also to be regarded as within the scope in which the present disclosure can be implemented.

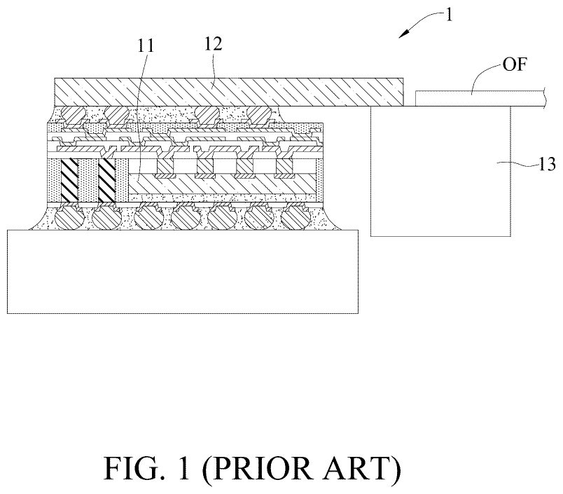

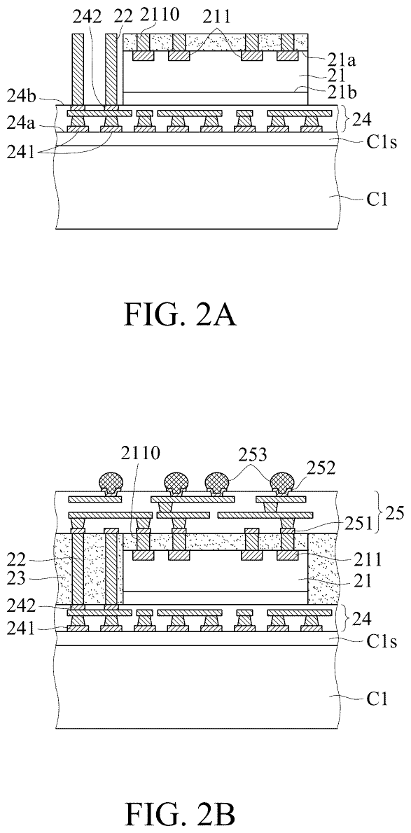

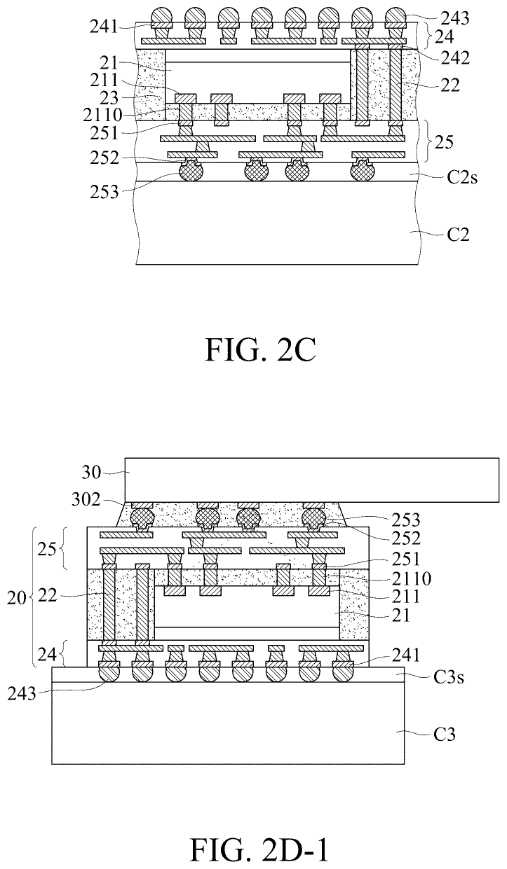

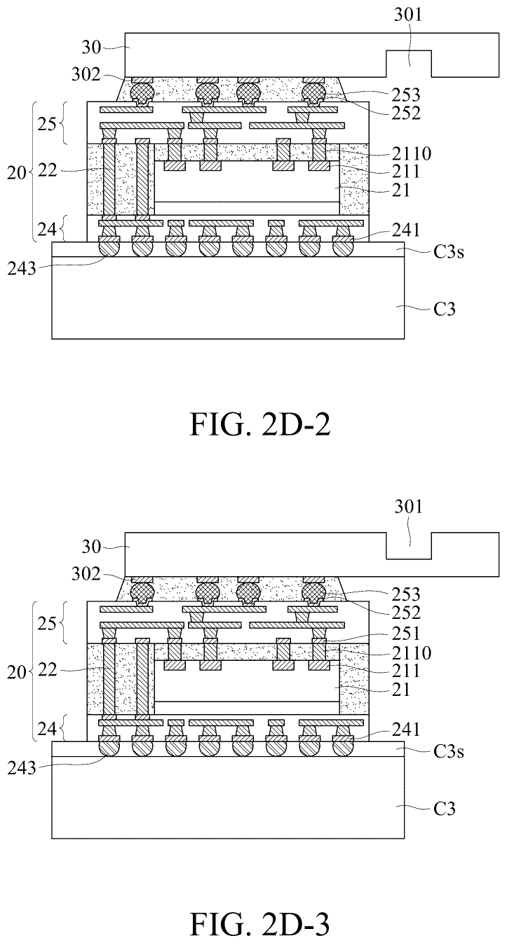

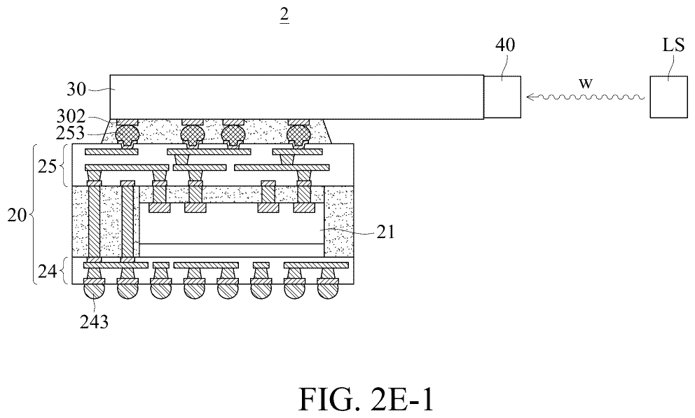

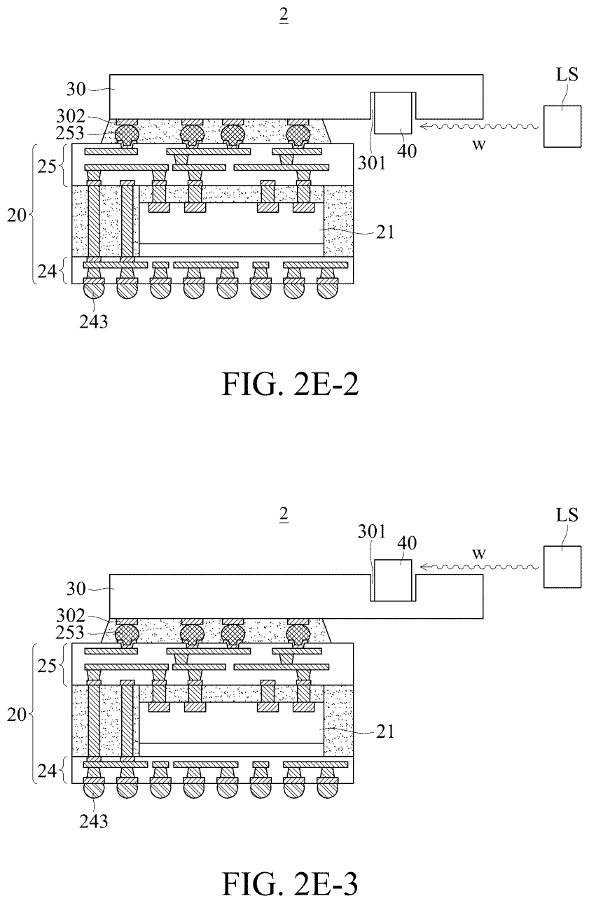

FIG. 2A to FIG. 2D-1 and FIG. 2E-1 are schematic views of an embodiment of an electronic package and a manufacturing method thereof according to the present disclosure.

In one embodiment, the manufacturing method includes providing an electronic module 20 as shown in FIG. 2D-1. In order to make the electronic module 20, first as shown in FIG. 2A, at least one electronic component 21 is bonded to a first circuit structure 24 disposed on a first carrier board C1.

The electronic component 21 has an active surface 21a and an inactive surface 21b that are opposite to each other, while the first circuit structure 24 has a first surface 24a and second surface 24b that are opposite to each other. The first circuit structure 24 is adhesively fixed on the first carrier board C1 through its first surface 24a by a first adhesive layer Cls, while the second surface 24b is connected to the inactive surface 21b of the electronic component 21.

The active surface 21a of the electronic component 21, the first surface 24a and the second surface 24b of the first circuit structure 24 have a plurality of connection pads 211, 241, 242, respectively, wherein a plurality of conductive bumps 2110 are disposed on the plurality of connection pads 211 of the electronic component 21, and a plurality of conductive pillars 22 are formed on the plurality of connection pads 242 of the second surface 24b of the first circuit structure 24.

In one embodiment, the electronic component 21 may be an active component, a passive component, or a combination thereof. The active component may be a semiconductor component such as a central processing unit (CPU), a graphics processing unit (GPU), or a memory chip, etc. The passive component may be a resistor, a capacitor, an inductor or a combination of any two or above of them. In one embodiment, the electronic component 21 is an electronic integrated circuit (EIC).

As shown in FIG. 2B, a space between the electronic component 21 and the conductive pillars 22 is filled out with an encapsulating material 23 such as an encapsulant, for a top surface of the encapsulating material 23 to be coplanar with top ends of the conductive pillars 22 and top ends of the plurality of conductive bumps 2110, such that the top ends of the conductive pillars 22 and the top ends of the plurality of conductive bumps 2110 are exposed from the top surface of the encapsulating material 23.

Next, a second circuit structure 25 is formed on the top ends of the conductive pillars 22 and the top surface of the encapsulating material 23. A top surface and a bottom surface of the second circuit structure 25 have a plurality of connection pads 251,252, respectively, provided thereon. The connection pads 251 on the bottom surface of the second circuit structure 25 correspond to and are electrically connected to the conductive pillars 22 and the plurality of conductive bumps 2110, respectively, and a conductive bump 253 such as a solder ball is formed on each of the connection pads 252 on the top surface of the second circuit structure 25.

One or more redistribution layer(s) (RDL) may be included in each of the first circuit structure 24 and the second circuit structure 25, thereby increasing the flexibility in connections between circuits between the first circuit structure 24, the electronic component 21, the second circuit structure 25 and an optoelectronic component 30.

As shown in FIG. 2C, the first carrier board C1 and the first adhesive layer Cls are removed, and a stacked structure composed of the aforementioned first circuit structure 24, the electronic component 21 and the second circuit structure 25 is disposed on a second carrier board C2 after being flipped, such that the second circuit structure 25 is attached on a second adhesive layer C2s on a surface of the second carrier board C2. Further, the first surface 24a of the first circuit structure 24 and the connection pads 241 disposed on the first surface 24a are exposed upwardly, therefore a conductive bump 243 such as a solder ball can be formed on each of the connection pads 241 on the first surface 24a, respectively.

As shown in FIG. 2D-1, the second carrier board C2 and the second adhesive layer C2s are then removed, and the stacked structure composed of the aforementioned first circuit structure 24, the electronic component 21 and the second circuit structure 25 is disposed on a third carrier board C3 after being flipped again, such that the conductive bumps 243 and the first circuit structure 24 are attached on the third carrier board C3 through a third adhesive layer C3s. Afterward, by cutting the excessive part on two sides of the stacked structure composed of the aforementioned first circuit structure 24, the electronic component 21 and the second circuit structure 25 off, the electronic module 20 is obtained.

Subsequently, an optoelectronic component 30 is disposed on the electronic module 20, for the optoelectronic component 30 to be electrically connected to the electronic module 20 through the plurality of connection pads 302 on the bottom surface of the optoelectronic component 30, the plurality of connection pads 252 disposed on the top surface of the second circuit structure 25, and the conductive bumps 253 connected between the connection pads 252,302.

As shown in FIG. 2E-1, a lens module 40, which is used to receive a light wave signal w emitted by an enteral laser source LS, is disposed on a side of the optoelectronic component 30. After the lens module 40 has been secured, the third carrier board C3 can be removed along with the third adhesive layer C3s. Through the above process, the electronic package 2 can be obtained.

In one embodiment, the optoelectronic component 30 is, for example, a photonic IC (PIC), which is used to convert the light wave signal w into an electronic signal and then to transmit the electronic signal to the electronic component 21 or others in the electronic module 20 to be processed or stored.

Furthermore, in addition to the lens module 40 being disposed on a side of the optoelectronic component 30 as mentioned above, in another aspect as shown in FIG. 2D-2 and FIG. 2E-2, a recess 301 may be formed on a bottom side of the optoelectronic component 30 after the optoelectronic component 30 is disposed on the electronic module 20, for an upper portion of the lens module 40 to be accommodated within the recess 301, and a remaining portion of the lens module 40 to bulge out from the recess 301 to receive a light wave signal w emitted form an outer laser source LS. In an aspect of an embodiment, the lens module 40 may include a reflection means or a refraction means such as a reflection lens or a refraction lens (not shown), to reflect or refract upwardly a light wave signal w incident laterally, such that the light wave signal w can be received by the optoelectronic component 30 and then be converted into an electronic signal to be transmitted to the electronic module 20 and the electronic component 21 therein.

In another aspect, as shown in FIG. 2D-3 and FIG. 2E-3, the recess 301 is formed on the top side of the optoelectronic component 30, for a lower portion of the lens module 40 to be accommodated within the recess 301, and a remaining portion of the lens module 40 to bulge out from the recess 301 to be used to receive a light wave signal w emitted form an outer laser source LS. Further, the lens module 40 includes a reflection lens or a refraction lens (not shown) that is used to reflect or refract downwardly a laterally incident light wave signal w, such that the light wave signal w can be received by the optoelectronic component 30.

In addition to the manufacturing method described above, the present disclosure further provides an electronic package 2, which comprises: an electronic module 20; an optoelectronic component 30 disposed on and electrically connected to the electronic module 20; and a lens module 40 disposed on a side of the optoelectronic component 30.

In some aspects of an embodiment, the electronic module 20 includes an electronic component 21, which is electrically connected to the optoelectronic component 30.

In some aspects of the embodiment, the electronic component 21 is an electronic IC (EIC).

In some aspects of the embodiment, the optoelectronic component 30 is a photonic IC (PIC).

In some aspects of the embodiment, the optoelectronic component 30 has a recess 301, such that a portion the lens module 40 is accommodated within the recess 301 and another portion of the lens module 40 bulges out from the recess 301.

In some aspects of the embodiment, the recess 301 is formed on a top side or a bottom side of the optoelectronic component 30.

To sum up, the electronic package and the manufacturing method thereof mainly provide a lens module for receiving optical signals in the form of lasers in the electronic package, so that the electronic package can be used in cooperation with the laser without the need to set a shelf for carrying and fixing the optical fiber. Therefore, the structure and manufacturing method thereof can be effectively simplified, thereby improving the yield and the speed of manufacture and then reducing the manufacturing costs.

The above embodiments are set forth to illustrate the principles of the present disclosure, and should not be interpreted as to limit the present disclosure. The above embodiments can be modified by one of ordinary skill in the art without departing from the scope of the present disclosure as defined in the appended claims. Therefore, the scope of protection of the right of the present disclosure should be listed as the following appended claims.

What is claimed is:

1. An electronic package, comprising:
an electronic module;
an optoelectronic component disposed on and electrically connected to the electronic module; and
a lens module disposed on a side of the optoelectronic component.

2. The electronic package of claim 1, wherein the electronic module includes an electronic component that is electrically connected to the optoelectronic component.

3. The electronic package of claim 2, wherein the electronic component is an electronic IC (EIC).

4. The electronic package of claim 1, wherein the optoelectronic component is a photonic IC (PIC).

5. The electronic package of claim 1, wherein the optoelectronic component has a recess, such that a portion of the lens module is accommodated within the recess and another portion of the lens module bulges out from the recess.

6. The electronic package of claim 5, wherein the recess is formed on a top side or a bottom side of the optoelectronic component.

7. A manufacturing method of an electronic package, comprising:
providing an electronic module;
disposing an optoelectronic component on the electronic module and electrically connecting the optoelectronic component to the electronic module; and
disposing a lens module on a side of the optoelectronic component.

8. The manufacturing method of claim 7, wherein the electronic module includes an electronic component that is electrically connected to the optoelectronic component.

9. The manufacturing method of claim 8, wherein the electronic component is an electronic IC (EIC).

10. The manufacturing method of claim 7, wherein the optoelectronic component is a photonic IC (PIC).

11. The manufacturing method of claim 7, wherein the optoelectronic component has a recess, such that a portion of the lens module is accommodated within the recess and another portion of the lens module bulges out from the recess.

12. The manufacturing method of claim 11, wherein the recess is formed on a top side or a bottom side of the optoelectronic component.
